(19) United States
(12) Patent Application Publication
(10) Pub. No.: US 2026/0190264 A1
(43) Pub. Date: Jul. 2, 2026

(54) DISPLAY DEVICE

(71) Applicant: LG Display Co., Ltd., Seoul (KR)

(72) Inventor: Kou CHOI, Paju-si (KR)

(73) Assignee: LG Display Co., Ltd., Seoul (KR)

(21) Appl. No.: 19/208,338

(22) Filed: May 14, 2025

(30) Foreign Application Priority Data
Dec. 26, 2024 (KR) 10-2024-0196877

(51) Int. Cl. H05K 5/03

(52) U.S. Cl. CPC H05K 5/03

(57) ABSTRACT

A display device in some examples can include a display panel to display an image, a cover member over the display panel, a rear cover under the display panel and having a first cover portion corresponding to a rear surface of the display panel and a second cover portion corresponding to a side surface of the display panel, and an adhesive member disposed between the second cover portion and the cover member. The rear cover further includes a third cover portion disposed between the second cover portion and the cover member. The transparency of the third cover portion is higher than the transparency of the first and second cover portions.

### CROSS-REFERENCE TO RELATED APPLICATION

The present application claims priority to Korean Patent Application No. 10-2024- 0196877 filed in the Republic of Korea on December 26, 2024, the entire contents of which are hereby expressly incorporated by reference into the present application.

### BACKGROUND

### Technical Field

The present disclosure relates to a display device, and more particularly, to a display device provided with an adhesive member.

### Discussion of the Related Art

As one of the flat panel display devices, an electroluminescent display device has wide viewing angles, as compared with a liquid crystal display device, because it is self-luminous. The electroluminescent display device also has advantages of a thin thickness, light weight and low power consumption because a backlight unit is not needed.

In addition, the electroluminescent display device is driven by low voltages of direct current (DC) and has a fast response time. Further, the electroluminescent display device is strong against the external impacts and is used in a wide range of temperatures because its components are solids. Furthermore, the electroluminescent display device can be manufactured at low costs.

The electroluminescent display device is widely used in portable devices such as smartphones, computer monitors, televisions, or vehicle instrument panels. A display module of the electroluminescent display device can be modularized through various instruments such as cases or covers.

In this case, by using an adhesive member for fixing and bonding between the display module and the instruments, a bezel area where an image is not displayed can be minimized. A thermosetting adhesive can be used as the adhesive member. However, since the thermosetting adhesive requires complex equipment and processes and has a relatively long curing time, it can be difficult to maintain the applied shape during the curing process, which can cause issues such as poor bonding.

### SUMMARY OF THE DISCLOSURE

Accordingly, embodiments of the present disclosure are directed to a display device that substantially obviates one or more of the problems due to limitations and disadvantages of the related art.

An aspect of the present disclosure is to provide a display capable of preventing a bonding failure due to an adhesive member.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a display device includes a display panel configured to display an image; a cover member over the display panel; a rear cover under the display panel and including a first cover portion corresponding to a rear surface of the display panel and a second cover portion corresponding to a side surface of the display panel; and an adhesive member disposed between the second cover portion and the cover member, wherein the rear cover further includes a third cover portion between the second cover portion and the cover member, and the transparency of the third cover portion is higher than the transparency of the first and second cover portions.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings.

FIG. 1 is a schematic cross-sectional view of a display device according to one or more embodiments of the present disclosure;

FIG. 2 is an enlarged cross-sectional view of an area A1 of FIG. 1;

FIG. 3 is a schematic cross-sectional view of a display panel of a display device according to an embodiment of the present disclosure;

FIGS. 4A to 4C are schematic views of components of a display device in steps/operations of manufacturing the display device according to one or more embodiments of the present disclosure;

FIG. 5 is a schematic plan view of a rear cover according to an embodiment of the present disclosure;

FIG. 6 is a schematic cross-sectional view of line I-I’ of FIG. 5;

FIG. 7 is a schematic cross-sectional view of line II-II’ of FIG. 5;

FIG. 8 is a schematic cross-sectional view of a rear cover according to another embodiment of the present disclosure; and

FIG. 9 is a schematic cross-sectional view of a rear cover according to another embodiment of the present disclosure.

### DETAILED DESCRIPTION OF THE EMBODIMENTS

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or can be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith. Further, the term “can” fully encompasses all the meanings and coverages of the term “may” and vice versa.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

Hereinafter, example embodiments of the present disclosure will be described in detail with reference to accompanying drawings. All the components of each display device according to all embodiments of the present disclosure are operatively coupled and configured.

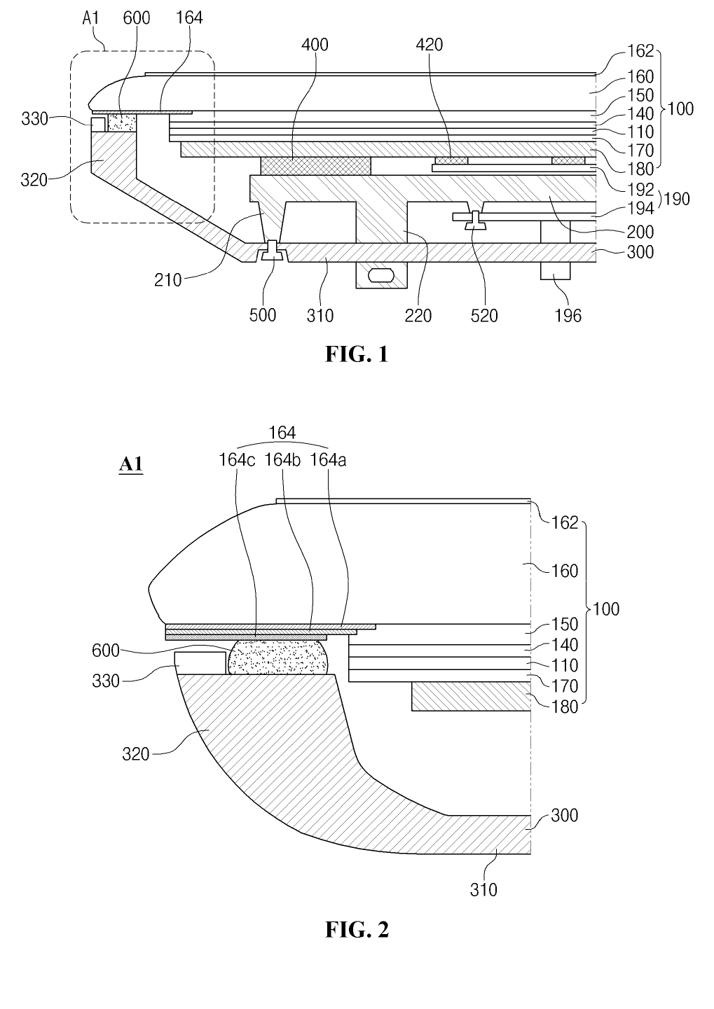

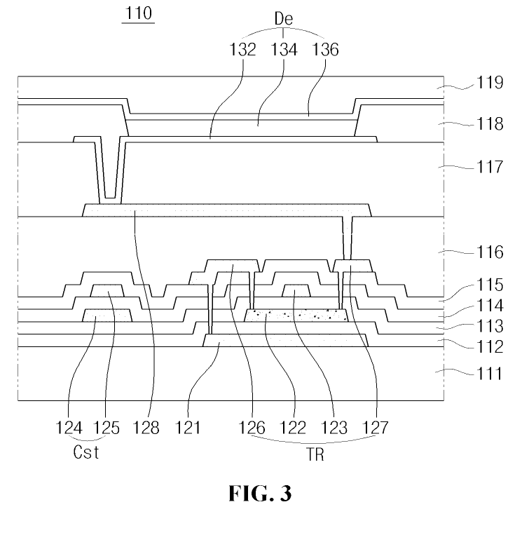

FIG. 1 is a schematic cross-sectional view of a display device according to one or more embodiments of the present disclosure, and FIG. 2 is an enlarged cross-sectional view of an area A1 of FIG. 1. The display device according to the embodiment(s) of the present disclosure can be a display device applied to a vehicle, but can be applied in other entities, environments, and technologies.

Referring to FIG. 1 and FIG. 2, the display device according to the embodiment of the present disclosure can include a display module 100, a driving part 190, a core plate 200, and a rear cover 300.

The display module 100 and the core plate 200 can be fixed to each other through a first adhesive tape 400. The core plate 200 and the rear cover 300 can be fixed to each other through a first screw 500. The display module 100 and the rear cover 300 can be fixed to each other through an adhesive member 600.

The display module 100 can include a display panel 110, a polarizer 140, an adhesive layer 150, a cover member 160, a back plate 170, and a heat dissipation plate 180.

The display panel 110 can include a plurality of sub-pixels to display an image. The image can be displayed through a top surface of the display panel 110 in the context of the figure. Here, a cross section of each sub-pixel can be configured as shown in FIG. 3.

FIG. 3 is a schematic cross-sectional view of a display panel of a display device according to an embodiment of the present disclosure.

Referring to FIG. 3, the display panel 110 of the display device according to the embodiment of the present disclosure can include a thin film transistor TR, a storage capacitor Cst, and a light-emitting diode De over a substrate 111.

Specifically, the substrate 111 can be formed of a transparent insulating material and, for example, can be a glass substrate or a plastic substrate. Polyimide can be used for the plastic substrate, and the plastic substrate can have a stacked structure including at least one polyimide layer and at least one inorganic layer. However, embodiments of the present disclosure are not limited thereto.

A light-shielding layer 121 can be provided over and in direct contact with the substrate 111. The light-shielding layer 121 can be formed of a conductive material such as metal. The light-shielding layer 121 can be formed of one or more of: aluminum (Al), copper (Cu), molybdenum (Mo), titanium (Ti), chromium (Cr), nickel (Ni), tungsten (W), and an alloy thereof. For example, the light-shielding layer 121 can have a single-layered structure or a multiple-layered structure.

A barrier layer can be further provided between the substrate 111 and the light-shielding layer 121. The barrier layer can be formed of an inorganic insulating material, such as silicon oxide (SiOx), silicon nitride (SiNx), or silicon oxynitride (SiON), and can be formed as a single layer or multiple layers.

A buffer layer 112 can be provided over the light-shielding layer 121. The buffer layer 112 can be formed of an inorganic insulating material, such as silicon oxide (SiOx), silicon nitride (SiNx), or silicon oxynitride (SiON), and can be formed as a single layer or multiple layers.

A semiconductor layer 122 can be provided over the buffer layer 112. The semiconductor layer 122 can overlap the light-shielding layer 121, and the light-shielding layer 121 can block light incident on the semiconductor layer 122, and reduce or prevent the semiconductor layer 122 from deteriorating due to the light.

The semiconductor layer 122 can include a channel region of the central portion and source and drain regions on both sides of the channel region. The semiconductor layer 122 can be formed of an oxide semiconductor material. Alternatively, the semiconductor layer 122 can be formed of polycrystalline silicon. In this case, both end portions of the semiconductor layer 122 can be doped with impurities.

A gate insulation layer 113 can be provided over the semiconductor layer 122. The gate insulation layer 113 can be formed of an inorganic insulating material, such as silicon oxide (SiOx), silicon nitride (SiNx), or silicon oxynitride (SiON), and can be formed as a single layer or multiple layers.

A gate electrode 123 and a first capacitor electrode 124 can be provided over the gate insulation layer 113.

The gate electrode 123 can overlap the semiconductor layer 122 and can be disposed to correspond to the central portion of the semiconductor 1ayer 122. Accordingly, the gate electrode 123 can overlap the light-shielding layer 121.

The first capacitor electrode 124 can be spaced apart from the gate electrode 123. The first capacitor electrode 124 can also be spaced apart from the light-shielding layer 121. However, embodiments of the present disclosure are not limited thereto. In other embodiments, the first capacitor electrode 124 can be in direct contact with the gate electrode 123 and be electrically connected to the gate electrode 123.

The gate electrode 123 and the first capacitor electrode 124 can be formed of a conductive material such as metal. The gate electrode 123 and the first capacitor electrode 124 can be formed of one or more of: aluminum (Al), copper (Cu), molybdenum (Mo), titanium (Ti), chromium (Cr), nickel (Ni), tungsten (W), and an alloy thereof. The gate electrode 123 and the first capacitor electrode 124 can have a single-layered structure or a multiple-layered structure.

A first interlayer insulation layer 114 can be provided over the gate electrode 123 and the first capacitor electrode 124. The first interlayer insulation layer 114 can be formed of an inorganic insulating material, such as silicon oxide (SiOx), silicon nitride (SiNx), or silicon oxynitride (SiON), and can be formed as a single layer or multiple layers.

A second capacitor electrode 125 can be provided over the first interlayer insulation layer 114. The second capacitor electrode 125 can overlap the first capacitor electrode 124 to thereby form the storage capacitor Cst with the first interlayer insulation layer 114 interposed therebetween as a dielectric.

The second capacitor electrode 125 can be formed of a conductive material such as metal. The second capacitor electrode 125 can be formed of one or more of: aluminum (Al), copper (Cu), molybdenum (Mo), titanium (Ti), chromium (Cr), nickel (Ni), tungsten (W), and an alloy thereof. For example, the second capacitor electrode 125 can have a single-layered structure or a multiple-layered structure.

A second interlayer insulation layer 115 can be provided over the second capacitor electrode 125. The second interlayer insulation layer 115 can be formed of an inorganic insulating material, such as silicon oxide (SiOx), silicon nitride (SiNx), or silicon oxynitride (SiON), and can be formed as a single layer or multiple layers.

A source electrode 126 and a drain electrode 127 can be provided over the second interlayer insulation layer 115. The source and drain electrodes 126 and 127 can be spaced apart from each other with the gate electrode 123 positioned therebetween and can be in contact with the both end portions of the semiconductor layer 122 through contact holes provided in the first and second interlayer insulation layers 114 and 115 and the gate insulation layer 113.

In addition, the source electrode 126 can be in contact with the light-shielding layer 121 through a contact hole provided in the first and second interlayer insulation layers 114 and 115, the gate insulation layer 113, and the buffer layer 112.

The source and drain electrodes 126 and 127 can be formed of one or more of: aluminum (Al), copper (Cu), molybdenum (Mo), titanium (Ti), chromium (Cr), nickel (Ni), tungsten (W), and an alloy thereof. The source and drain electrodes 126 and 127 can have a single-layered structure or a multiple-layered structure.

The source and drain electrodes 126 and 127, the gate electrode 123, and the semiconductor layer 122 can form the thin film transistor TR. The thin film transistor TR can be a driving transistor, and one or more transistors having substantially the same configuration as the thin film transistor TR can be further provided over the substrate 111. However, embodiments of the present disclosure are not limited thereto.

Meanwhile, one of the first and second interlayer insulation layers 114 and 115 can be omitted, and in this case, the second capacitor electrode 125 can be provided of the same material and over the same layer as the source and drain electrodes 126 and 127.

A first planarization layer 116 can be provided over the source and drain electrodes 126 and 127. The first planarization layer 116 can eliminate a step difference due to the layers thereunder and can have a substantially flat top surface. The first planarization layer 116 can be formed of an organic insulating material such as photosensitive acrylic polymer (photo acryl.)

A connection electrode 128 can be provided over the first planarization layer 116. The connection electrode 128 can be in contact with the drain electrode 127 through a contact hole provided in the first planarization layer 116.

The connection electrode 128 can overlap the thin film transistor TR and the storage capacitor Cst. However, embodiments of the present disclosure are not limited thereto. In other embodiments, the connection electrode 128 can overlap a part of the thin film transistor TR and be in spaced apart from the storage capacitor Cst.

The connection electrode 128 can be formed of a conductive material such as metal. The connection electrode 128 can be formed of one or more of: aluminum (Al), copper (Cu), molybdenum (Mo), titanium (Ti), chromium (Cr), nickel (Ni), tungsten (W), and an alloy thereof. For example, the connection electrode 128 can have a single-layered structure or a multiple-layered structure.

A second planarization layer 117 can be provided over the connection electrode 128. The second planarization layer 117 can eliminate a step difference due to the layers thereunder and can have a substantially flat top surface. The second planarization layer 117 can be formed of an organic insulating material such as photosensitive acrylic polymer (photo acryl).

Next, a first electrode 132 can be provided over the second planarization layer 117 and can be formed of a conductive material having relatively high work function. The first electrode 132 can be in contact with the connection electrode 128 through a contact hole provided in the second planarization layer 117. Accordingly, the first electrode 132 can be electrically connected to the drain electrode 127 through the connection electrode 128.

Alternatively, the connection electrode 128 and the second planarization layer 117 can be omitted. In this case, the first electrode 132 can be disposed over the first planarization layer 116 and can be in direct contact with the drain electrode 127 through a contact hole provided in the first planarization layer 116.

For example, the first electrode 132 can include a transparent conductive material such as indium tin oxide (ITO) or indium zinc oxide (IZO) or include titanium (Ti). However, embodiments of the present disclosure are not limited thereto.

Meanwhile, the first electrode 132 can have a multi-layered structure including a material with relatively high reflectance. For example, the first electrode 132 can be formed as a structure having relatively high reflectance such as a triple-layered structure of titanium, aluminum, and titanium (Ti/Al/Ti), a triple-layered structure of indium tin oxide, aluminum, and indium tin oxide (ITO/Al/ITO), a triple-layered structure of indium tin oxide, silver, and indium tin oxide (ITO/Ag/ITO), or a triple-layered structure of indium tin oxide, silver alloy, and indium tin oxide (ITO/Ag alloy/ITO). Here, the silver alloy can be an alloy of silver-palladium-copper (APC).

A bank layer 118 of an organic insulating material can be provided over the first electrode 132. The bank layer 118 can overlap edges of the first electrode 132 and cover the edges of the first electrode 132. The bank layer 118 can expose a central portion of the first electrode 132.

A light-emitting layer 134 can be provided over the first electrode 132 exposed by the bank layer 118. The light-emitting layer 134 can emit one light of red, green, and blue colors.

The light-emitting layer 134 can include at least one hole auxiliary layer, at least one light-emitting material layer, and at least one electron auxiliary layer constituting one light-emitting unit.

The light-emitting material layer can include one of red, green, and blue luminescent materials. The luminescent material can be an organic luminescent material such as a phosphorescent compound or a fluorescent compound or can be an inorganic luminescent material such as a quantum dot.

The hole auxiliary layer can include at least one of a hole injection layer (HIL) and a hole transport layer (HTL). The electron auxiliary layer can include at least one of an electron injection layer (EIL) and an electron transport layer (ETL).

As shown in the figure, the light-emitting layer 134 can be disposed only over the first electrode 132 exposed by the bank layer 118.

However, embodiments of the present disclosure are not limited thereto. In other embodiments, some of the light-emitting layer 134, for example, the light-emitting material layer can be disposed only over the first electrode 132, and the hole auxiliary layer and the electron auxiliary layer can be disposed substantially all over the substrate 111.

Alternatively, in other embodiments, the light-emitting layer 134 can emit white light and can be provided on top and side surfaces of the bank layer 118, so that the light-emitting layer 134 can be disposed substantially all over the substrate 111. In this case, the light-emitting layer 134 can include a plurality of light-emitting units emitting light of different colors and being stacked. Each stack can include at least one hole auxiliary layer, at least one light-emitting material layer, and at least one electron auxiliary layer.

For example, the light-emitting layer 134 can have a stack structure in which two or more light-emitting units emitting different colors are stacked, and a charge generation layer (CGL) can be provided between two or more light-emitting units.

A second electrode 136 of a conductive material with relatively low work function can be provided over the light-emitting layer 134. The second electrode 136 can be disposed substantially all over the substrate 111.

The second electrode 136 can be formed of aluminum (Al), magnesium (Mg), silver (Ag), or an alloy thereof. In this case, the second electrode 136 can have a relatively thin thickness such that light from the light-emitting layer 134 can be transmitted therethrough. For example, the second electrode 136 can have a thickness of about 5 nm to about 10 nm, but embodiments of the present disclosure are not limited thereto.

Alternatively, the second electrode 136 can be formed of a transparent conductive material such as indium gallium oxide (IGO) or IZO.

The first electrode 132, the light-emitting layer 134, and the second electrode 136 can constitute the light-emitting diode De. Here, the first electrode 132 can serve as an anode, and the second electrode 136 can serve as a cathode. However, embodiments of the present disclosure are not limited thereto. In other embodiments, the first electrode 132 can serve as a cathode, and the second electrode 136 can serve as an anode.

An encapsulation layer 119 can be provided over the second electrode 136 and disposed substantially all over the substrate 111. The encapsulation layer 119 can protect the light-emitting diode De from external moisture or oxygen. The encapsulation layer 119 can include at least one inorganic layer and at least one organic layer. Here, the organic layer can be a layer covering particles that are generated during the manufacturing process.

Meanwhile, a capping layer can be provided between the second electrode 136 and the encapsulation layer 119. The capping layer can be formed of an insulating material having a relatively high refractive index. The wavelength of light traveling along the capping layer can be amplified by surface plasma resonance. Thus, the intensity of the peak can be increased, thereby improving the light efficiency in the display device. For example, the capping layer can be formed as a single layer of an organic layer or an inorganic layer, or can be formed as organic/inorganic stacked layers.

In addition, a sensor portion can be provided over the encapsulation layer 119 to detect an external input such as touch.

Referring to FIG. 1 and FIG. 2 again, the polarizer 140 can be provided over the display panel 110. The polarizer 140 can be attached to the display panel 110 through an optical adhesive or a pressure sensitive adhesive (PSA).

The polarizer 140 can be intended to reduce reflection of external light, for example, to prevent or minimize the external light from being output to the outside after being reflected by the display panel 110. For example, the polarizer 140 can be a circular polarizing plate including a linear polarizer and a retardation film.

The adhesive layer 150 can be provided over the polarizer 140. The adhesive layer 150 can be transparent and can have an area corresponding to substantially the entire top surface of the display panel 110. The adhesive layer 150 can be optically clear adhesive (OCA) that is manufactured and attached in a film form or optically clear resin (OCR) that is applied as a liquid material and then hardened.

The cover member 160 can be provided over the adhesive layer 150. The cover member 160 can be attached to the polarizer 140 through the adhesive layer 150. The cover member 160 can have a larger area than the top surface of the display panel 110.

The cover member 160 can be formed of a transparent material. For example, the cover member 160 can be formed of glass. Alternatively, the cover member 160 can be formed of a polymer resin such as polyimide (PI), polyaramid (PA), polycarbonate (PC), cyclo-olefin polymer (COP), polymethyl methacrylate (PMMA), or polyethylene terephthalate (PET). However, embodiments of the present disclosure are not limited thereto.

A protection film 162 can be provided over a top surface of the cover member 160. The protection film 162 can be disposed substantially the entire top surface of the cover member 160 to protect the top surface of the cover member 160. The protection film 162 can have a larger area than the top surface of the display panel 110.

For example, the protection film 162 can be formed of polyethylene terephthalate (PET) or thermoplastic polyurethane (TPU), but embodiments of the present disclosure are not limited thereto.

A light-blocking pattern 164 can be provided at an edge of a bottom surface of the cover member 160. The light-blocking pattern 164 can block light from the display panel 110 from being emitted to a side surface of the display module 100.

The light-blocking pattern 164 can have a first light-blocking pattern 164a, a second light-blocking pattern 164b, and a third light-blocking pattern 164c sequentially disposed from the bottom surface of the cover member 160.

The first and second light-blocking patterns 164a and 164b can be formed of the same material. For example, the first and second light-blocking patterns 164a and 164b can be formed of a black resin including black particles in a resin. The black particles can be a pigment and/or carbon black.

The first and second light-blocking patterns 164a and 164b can be formed by a printing method. If the light-blocking pattern 164 is formed by one printing process, air bubbles can be generated, which can cause light leakage. Accordingly, by laminating the first and second light-blocking patterns 164a and 164b, the light-blocking pattern 164 can be formed by two printing processes.

The first and second light-blocking patterns 164a and 164b can overlap and be in contact with the adhesive layer 150. In this case, the first and second light-blocking patterns 164a and 164b can have different widths and areas. Specifically, the width and area of the first light-blocking pattern 164a in contact with the cover member 160 can be greater than the width and area of the second light-blocking pattern 164b not in contact with the cover member 160. Therefore, the first and second light-blocking patterns 164a and 164b can form a step difference on the inside thereof, and when the cover member 160 provided with the light-blocking pattern 164 is attached to the adhesive layer 150, air bubbles can be prevented from being generated.

Meanwhile, the third light-blocking pattern 164c can be formed of a different material from the first and second light-blocking patterns 164a and 164b. For example, the third light-blocking pattern 164c can be formed of a metallic material having relatively high reflectance such as silver (Ag), aluminum (Al), or chromium (Cr).

The third light-blocking pattern 164c can increase light efficiency by reflecting UV light incident thereon when the adhesive member 600 is cured and allowing it to reach the adhesive member 600, which will be described in detail later.

Here, the third light-blocking pattern 164c can have a different width and area from the first and second light-blocking patterns 164a and 164b. Specifically, the width and area can be smaller than those of the first and second light-blocking patterns 164a and 164b. Accordingly, the width and area of the second light-blocking pattern 164b can be greater than the width and area of the third light-blocking pattern 164c and smaller than the width and area of the first light-blocking pattern 164a.

The third light-blocking pattern 164c can be spaced apart from the adhesive layer 150 without overlapping the adhesive layer 150. If the third light-blocking pattern 164c overlaps and contacts the adhesive layer 150, air bubbles can be generated due to an increase in a step difference between the first, second, and third light-blocking patterns 164a, 164b, and 164c, and thus the third light-blocking pattern 164c can be disposed to be spaced apart from the adhesive layer 150. For example, a distance between the third light-blocking pattern 164c and the adhesive layer 150 can be 0.5 mm or more, but embodiments of the present disclosure are not limited thereto.

In addition, a thickness of the third light-blocking pattern 164c can be smaller than a thickness of each of the first and second light-blocking patterns 164a and 164b. For example, the thickness of each of the first and second light-blocking patterns 164a and 164b can be 10 μm to 15 μm, and the thickness of the third light-blocking pattern 164c can be 5 μm to 10 μm. However, embodiments of the present disclosure are not limited thereto

Next, the back plate 170 can be provided under the display panel 110. The back plate 170 can support and protect the display panel 110. The back plate 170 can be attached to the display panel 110 through an optical adhesive or a pressure sensitive adhesive.

For example, the back plate 170 can be formed of polyethylene terephthalate (PET) or polycarbonate (PC), but embodiments of the present disclosure are not limited thereto.

The heat dissipation plate 180 can be provided under the back plate 170. The heat dissipation plate 180 can dissipate heat generated from the display panel 110 or the driving part 190 to the outside. The heat dissipation plate 180 can be attached to the back plate 170 through an optical adhesive or a pressure sensitive adhesive.

For example, the heat dissipation plate 180 can be formed of a metallic material having relatively high thermal conductivity such as aluminum (Al), and a thickness of the heat dissipation plate 180 can be greater than that of the display panel 110 or the back plate 170.

The driving part 190 can be disposed over a rear surface of the display module 100. The driving part 190 can include a source printed circuit board 192 and a control printed circuit board 194.

The source printed circuit board 192 can be disposed between the heat dissipation plate 180 and the core plate 200 and can be attached to the heat dissipation plate 180 through a second adhesive tape 420.

The source printed circuit board 192 can supply signals for driving the display module 100 and can be connected to the display module 100 through a flexible printed circuit. The flexible printed circuit can be a chip on film (COF) type including a source driver integrated circuit (IC) chip.

The control printed circuit board 194 can be disposed between the core plate 200 and the rear cover 300 and can be fixed to the core plate 200 through a second screw 520.

The control printed circuit board 194 can supply signals for driving the display module 100 and the vehicle. The control printed circuit board 194 can be connected to the source printed circuit board 192 through a flat cable and connected to a vehicle control part through a connector 196.

The core plate 200 can be provided between the source printed circuit board 192 and the control printed circuit board 194. The core plate 200 can be attached to the heat dissipation plate 180 of the display module 100 through the first adhesive tape 400. In this case, a thickness of the first adhesive tape 400 can be greater than a total thickness of the source printed circuit board 192 and the second adhesive tape 420.

First, second, and third fastening portions 210, 220, 230 can be provided on a rear surface of the core plate 200. The first fastening portion 210 can be combined with the rear cover 300 through the first screw 500, the second fastening portion 220 can be assembled with a trim of an instrument panel (IP) provided in a dashboard area of the vehicle, and the third fastening portion 230 can be combined with the control printed circuit board 194 through the second screw 520.

The rear cover 300 can be provided under the core plate 200. The rear cover 300 can be referred to as a set cover or a back cover. The rear cover 300 can include a first cover portion 310 corresponding to the rear surface of the display module 100 and a second cover portion 320 corresponding to the side surface of the display module 100.

The rear cover 300 including the first and second cover portions 310 and 320 can be opaque and block light. For example, the rear cover 300 can be formed of polycarbonate (PC) and acrylonitrile butadiene styrene (ABS).

The rear cover 300 can further include a third cover portion 330. The third cover portion 330 can be disposed between the second cover portion 320 and the cover member 160 and located outside the adhesive member 600. A thickness of the third cover portion 330 can be smaller than a thickness of the adhesive member 600. Accordingly, the third cover portion 330 can be in contact with the second cover portion 320 and be spaced apart from the third light-blocking pattern 164c of the light-blocking pattern 164. In this case, a distance between the third cover portion 330 and the third light-blocking pattern 164c can be smaller than the thickness of the third cover portion330.

The third cover portion 330 can be transparent and transmit light. The third cover portion 330 can be formed of a different material from the first and second cover portions 310 and 320. For example, the third cover portion 330 can be formed of polycarbonate (PC).

The rear cover 300 including the first, second and third cover portions 310, 320, and 330 can be molded by a double injection molding method. Specifically, the first and second cover portions 310 and 320 can be formed by mixing and melting PC and ABS and injection molding the mixture, and then the third cover portion 330 can be formed by injection molding PC.

Meanwhile, the adhesive member 600 can be provided between the rear cover 300 and the display module 100. Here, the adhesive member 600 can be a glue pattern using a photocurable adhesive.

Specifically, the adhesive member 600 can be disposed between the second cover portion 320 of the rear cover 300 and the cover member 160 of the display module 100 corresponding to the light-blocking pattern 164. The adhesive member 600 can be in contact with the second cover portion 320 and the third light-blocking pattern 164c. The third cover portion 330 can be located outside the adhesive member 600, and thus, the adhesive member 600 can be disposed between the third cover portion 330 and the display panel 110 in a horizontal direction in the context of the figure.

The adhesive member 600 can be formed of a photocurable adhesive. For example, the photocurable adhesive can include at least one of an acrylic resin, an epoxy resin, a urethane resin and a silicone resin, but is not limited thereto.

The photocurable adhesive can be one-component adhesive in which a main material and a hardener are premixed and which is curable. The one-component adhesive can be photo-cured by mixing and applying a photo-initiator and irradiating UV light, so that the curing time can be relatively short.

On the other hand, a conventional thermosetting adhesive can be a two-component adhesive in which a main agent and a hardener are mixed and then used. The two-component adhesive can cause nozzle clogging, so it is difficult to manage the process. As mentioned above, there is a problem in that it is difficult to manage the coating shape until heat curing after application.

In contrast, the adhesive member 600 according to aspects of the present disclosure can be substantially opaque and block light. In this case, the adhesive member 600 can have higher transparency than the first and second cover portions 310 and 320 such that UV light can pass therethrough and be irradiated to the photo-initiator. In addition, the adhesive member 600 can have lower transparency than the third cover portion 330 such that light from the display panel 110 can be blocked from being emitted to the side surface of the display module 100. For example, the transparency of the adhesive member 600 can be higher than the transparency of the first and second cover portions 310 and 320 and lower than the transparency of the third cover portion 330.

An optical density (OD) value of the adhesive member 600 can be greater than an OD value of the third cover portion 330 and smaller than an OD value of the first and second cover portions 310 and 320.

For example, the OD value of the adhesive member 600 can be 6.0 or more, but is not limited thereto.

As such, in the display device according to the embodiment of the present disclosure, the adhesive member 600 can be formed of the photocurable adhesive.

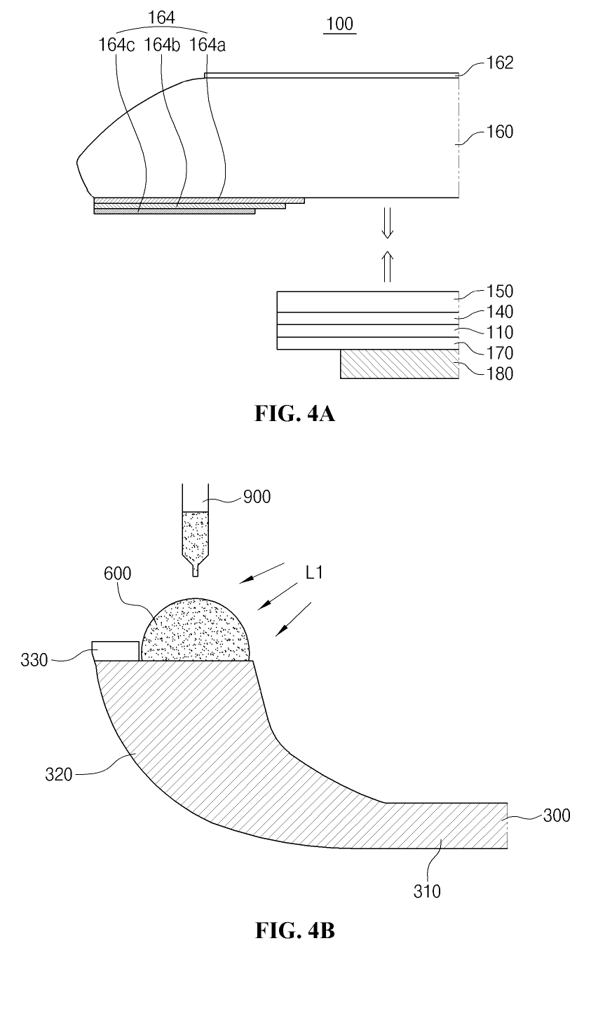

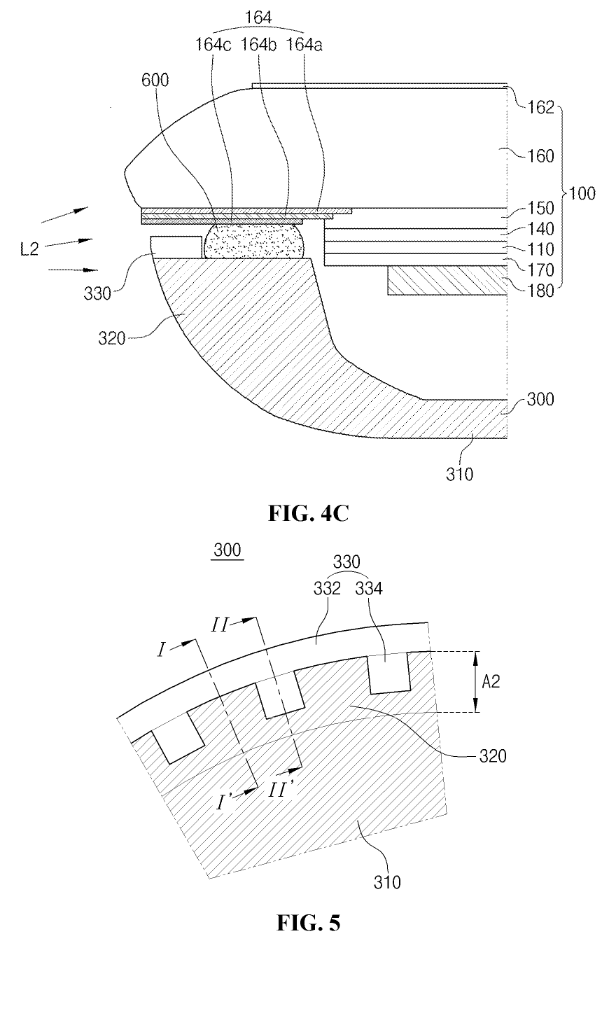

A method of manufacturing a display device according to an embodiment of the present disclosure in which the adhesive member 600 is formed using the photocurable adhesive will be described in detail with reference to FIGS. 4A to 4C

FIGS. 4A to 4C are schematic views of components of a display device in steps of manufacturing the display device according to the embodiment of the present disclosure.

First, Referring to FIG. 4A, the display panel 110, the polarizer 140, the adhesive layer 150, the back plate 170, and the heat dissipation plate 180 can be combined with each other, and the cover member 160 provided with the protection 162 and the light-blocking pattern 164 can be attached to the adhesive layer 150 to thereby complete the display panel 100.

Next, Referring to FIG. 4B, a nozzle 900 can be disposed over the rear cover 300. A material of the adhesive member 600 can be applied on a top surface of the second cover portion 320 inside the third cover portion 330 and then first cured by irradiating first light L1. In this case, the first curing time can be within a few seconds.

Meanwhile, the first light L1 can be illustrated as being irradiated from the inside of the rear cover 300, but embodiments of the present disclosure are not limited thereto. The first light L1 can also be irradiated from the outside of the rear cover 300.

Next, Referring to FIG. 4C, the display module 100 can be disposed over the first cured adhesive member 600, and the light-blocking pattern 164 can be brought into contact with the adhesive member 600. Then, the adhesive member 600 can be second cured by irradiating second light L2 from the outside of the rear cover 300. In this case, the second curing time can be within several tens of seconds, for example, less than a minute, and can be significantly shorter than the curing time of the thermosetting adhesive.

Accordingly, since the curing time after application is relatively short, a relatively high height of the adhesive member 600 can be implemented compared to the width of the adhesive member 600, so that a desired height can be implemented with a narrow area.

The second light L2 can reach the adhesive member 600 through a space between the second cover portion 320 and the light-blocking pattern 164. In this case, the second light L2 can pass through the third cover portion 330 and reach the adhesive member 600.

If the third cover portion 330 is opaque, since the second light L2 is irradiated to the adhesive member 600 through a very narrow space between the third cover portion 330 and the light-blocking pattern 164, the adhesive member 600 cannot be sufficiently cured, and it is impossible to secure the necessary adhesive strength.

However, in the embodiment of the present disclosure, the third cover portion 330 can be configured to be transparent so that the second light L2 can be sufficiently irradiated to the adhesive member 600. For example, the second light L2 can reach the adhesive member 600 through the space between the second cover portion 320 and the third light-blocking pattern 164c.

For example, a distance between the second cover portion 320 and the third light-blocking pattern 164c can be about 0.6 mm, and the distance between the third cover portion 330 and the third light-blocking pattern 164c can be less than 0.3 mm. However, embodiments of the present disclosure are not limited thereto.

Further, as mentioned above, since the third light-blocking pattern 164c is formed of a metallic material having relatively high reflectance, the second light L2 directed to the cover member 160 between the third cover portion 330 and the third light-blocking pattern 164c can be reflected by the third light-blocking pattern 164c and reach the adhesive member 600. Accordingly, it is possible to increase the amount of light reaching the adhesive member 600.

Here, the first light L1 and the second light L2 can be UV light, and a wavelength of the second light L2 can be shorter than a wavelength of the first light L1. For example, energy of the second light L2 can be greater than energy of the first light L1. For example, the wavelength of the first light L1 can be 400 nm or more, and the wavelength of the second light L2 can be 370 nm or less. However, embodiments of the present disclosure are not limited thereto.

As such, in the embodiments of the present disclosure, by forming the adhesive member 600 using the thermosetting adhesive, the manufacturing process can be simplified, and the manufacturing time can be decreased.

Accordingly, by managing the aspect ratio of the adhesive member 600, it is possible to implement a desired height within a narrow area.

In addition, since the third cover portion 330 is configured to be transparent to increase the amount of light reaching the adhesive member 600, it is possible to secure the necessary adhesive strength.

Further, the OD value of the adhesive member 600 can be configured to be 6.0 or more, thereby blocking light from the display panel 110 from being emitted to the side surface of the display module 100.

Meanwhile, to prevent the third cover portion 330 from being separated from the second cover portion 320, a part of the third cover portion 330 can be fixed in the second cover portion 320. A configuration of the rear cover 300 will be described with reference to FIGS. 5 to 7.

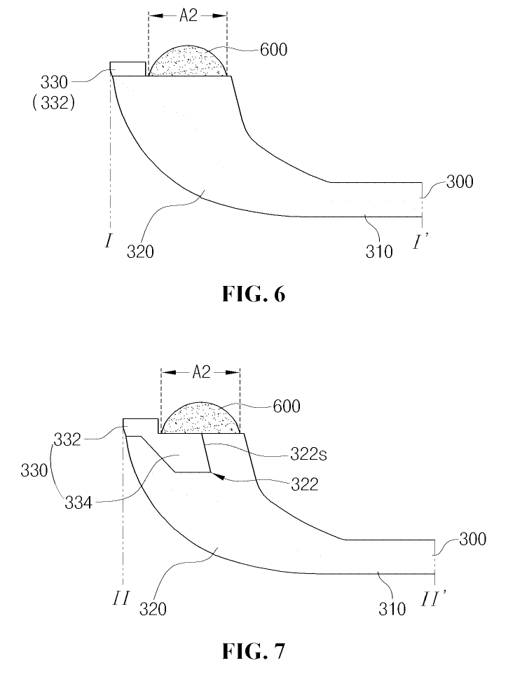

FIG. 5 is a schematic plan view of a rear cover according to an embodiment of the present disclosure, FIG. 6 is a schematic cross-sectional view of line I-I’ of FIG. 5, and FIG. 7 is a schematic cross-sectional view of line II-II’ of FIG. 5.

Referring to FIGS. 5 to 7, the third cover portion 330 can include a first part 332 and a second part 334.

The first part 332 can protrude upward from the top surface of the second cover portion 320. In this case, the first part 332 can be disposed to correspond to an outer edge of the top surface of the second cover portion 320.

On the other hand, the second part 334 can be provided in the second cover part 320. Specifically, the second cover portion 320 can have cover recesses 322 on the inner side from the first part 332, for example, on the side facing the display panel 110 of FIG. 2. The cover recesses 322 can partially overlap the first part 332. The cover recesses 322 can be spaced apart from each other along the top surface of the second cover portion 320, and the second part 334 can be connected to the first part 332 and disposed in each cover recess 322.

In this case, an inner wall 322s of the cover recess 322 can have a reverse slop, for example, a reverse inclination with respect to the top surface of the second cover portion 320. Accordingly, the third cover portion 330 can be prevented from being separated vertically from the second cover portion 320.

Here, the top surface of the second cover portion 320 except for the first part 332 of the third cover portion 330 can be an area A2 where the adhesive member 600 is applied. For example, the adhesive member 600 can be applied on the top surface of the second cover portion 320 and a top surface of the second part 334 of the third cover portion 330. Accordingly, the adhesive member 600 can be in contact with the top surface of the second cover portion 320 and the top surface of the second part 334 of the third cover portion 330.

Meanwhile, the adhesive member 600 can be in contact with a side surface of the first part 332 of the third cover portion 330.

FIG. 8 is a schematic cross-sectional view of a rear cover according to another embodiment of the present disclosure.

Referring to FIG. 8, the third cover portion 330 can include the first part 332, the second part 334, and a third part 336. Namely, in another embodiment of the present disclosure, the third cover portion 330 can further include the third part 336 compared to the previous embodiment.

The third part 336 can extend vertically from a lower portion of the second part 334 and can be provided in the second cover portion 320. The cover recess 322’ of the second cover portion 320 can further include a recess portion corresponding to the third part 336.

Accordingly, the third cover portion 330 of the rear cover 300 according to another embodiment of the present disclosure can be prevented from being separated vertically from the second cover portion 320 due to the inner wall 322s of the cover recess 322 having the reverse inclination and also prevented from being separated horizontally from the second cover portion 320 due to the third part 336 extending horizontally.

As such, the rear cover 300 according to another embodiment of the present disclosure can further prevent the third cover portion 330 from being separated from the second cover portion 320 compared to the previous embodiment.

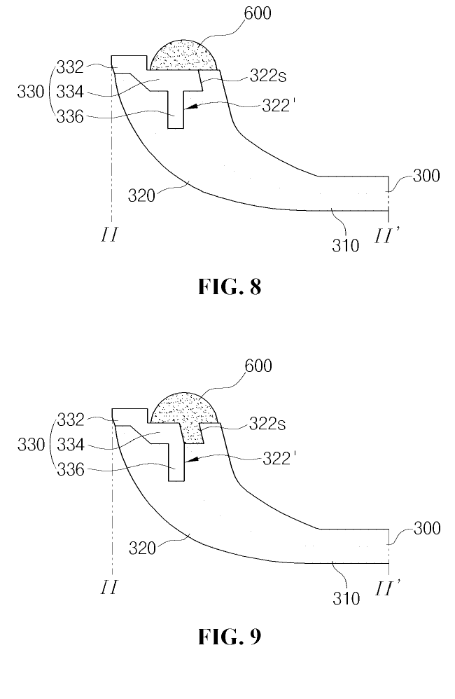

FIG. 9 is a schematic cross-sectional view of a rear cover according to another embodiment of the present disclosure.

Referring to FIG. 9, the third cover portion 330 can include the first part 332, the second part 334, and the third part 336, and the adhesive member can be partially provided in the cover recess 322’.

Specifically, the second part 334 of the third cover portion 330 can be spaced apart from the inner wall 322s of the cover recess 322’, and the adhesive member 600 can be provided in the cover recess 322’ between the second part 334 and the inner wall 322s.

Accordingly, the adhesive member 600 can be in contact with the side surface of the second part 334 as well as the top surface of the second part 334 and also be in contact with the inner wall 322s in the cover recess 322’. The contact area between the adhesive member 600 and the second and third cover portions 320 and 330 can be wider than in the previous embodiments

As such, since the contact area between the second and third cover portions 320 and 330 and the adhesive member 600 increases, the rear cover 300 according to another embodiment of the present disclosure can further prevent the third cover portion 330 from being separated from the second cover portion 320 compared to the previous embodiments.

In the display device according to aspects of the present disclosure, by forming the adhesive member for fixing the display module and the rear cover with a photocurable adhesive, the manufacturing process can be simplified, and the manufacturing time can be reduced. Accordingly, it is possible to reduce production energy by optimizing the manufacturing process of the display device.

In addition, according to aspects of the present disclosure, a part of the rear cover can be configured to be transparent, and the adhesive member can be cured, so that the necessary adhesion can be secured.

Further, according to aspects of the present disclosure, since the adhesive member is configured to be substantially opaque, it is possible to block light emitted from the side surface of the display module.

Moreover, according to aspects of the present disclosure, some of the light-blocking pattern contacting the adhesive member can be formed of a material that reflects light, thereby increasing light efficiency during the curing process of the adhesive member.

It will be apparent to those skilled in the art that various modifications and variations can be made in the electroluminescent display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device comprising:
a display panel configured to display an image;
a cover member over the display panel;
a rear cover under the display panel, the rear cover including a first cover portion corresponding to a rear surface of the display panel and a second cover portion corresponding to a side surface of the display panel; and
an adhesive member between the second cover portion and the cover member,
wherein the rear cover further includes a third cover portion between the second cover portion and the cover member, and
wherein a transparency of the third cover portion is higher than a transparency of each of at least one of the first and second cover portions.

2. The display device of claim 1, wherein the adhesive member is disposed between the third cover portion and the display panel.

3. The display device of claim 1, wherein an optical density value of the adhesive member is greater than an optical density value of the third cover portion and is smaller than an optical density value of each of at least one of the first and second cover portions.

4. The display device of claim 1, wherein the third cover portion includes:
a first part protruding upward from a top surface of the second cover portion, and
a second part disposed in a cover recess of the second cover portion.

5. The display device of claim 4, wherein an inner wall of the cover recess has a reverse inclination with respect to the top surface of the second cover portion.

6. The display device of claim 5, wherein the third cover portion further includes a third part extending vertically from a lower portion of the second part of the third cover portion, and is disposed in the second cover portion.

7. The display device of claim 6, wherein the second part of the third cover portion is spaced apart from the inner wall of the cover recess, and
wherein the adhesive member is provided in the cover recess between the second part of the third cover portion and the inner wall of the cover recess.

8. The display device of claim 1, further comprising a light-blocking pattern between the adhesive member and the cover member,
wherein the light-blocking pattern includes a first light-blocking pattern, a second light-blocking pattern, and a third light-blocking pattern sequentially provided from the cover member.

9. The display device of claim 8, wherein the first and second light-blocking patterns include a same material, and the third light-blocking pattern includes a different material from the first and second light-blocking patterns.

10. The display device of claim 8, wherein the third light-blocking pattern is formed of a material configured to reflect light.

11. The display device of claim 8, wherein a width and an area of the second light-blocking pattern are greater than a width and an area of the third light-blocking pattern and is smaller than a width and an area of the first light-blocking pattern.

12. The display device of claim 11, further comprising an adhesive layer between the display panel and the cover member,
wherein the adhesive layer overlaps and contacts the first and second light-blocking patterns, and is spaced apart from the third light-blocking pattern.

13. The display device of claim 8, wherein ends of the first to third light-blocking patterns form multiple steps.

14. The display device of claim 8, wherein a thickness of the third light-blocking pattern is smaller than a thickness of each of at least one of the first and second light-blocking patterns.
